(19) United States
(12) Patent Application Publication
(10) Pub. No.: US 2003/0235316 A1
(43) Pub. Date: Dec. 25, 2003

(54) Method and apparatus for recording live performances

(76) Inventors: Marc A. Chambers, Scottsdale, AZ (US); Dennis Wodarz, Phoenix, AZ (US); Erik C. Stubblebine, Phoenix, AZ (US)

Correspondence Address: CAHILL, SUTTON & THOMAS P.L.C., Attn: Marvin A. Glazer, 155 Park One, 2141 East Highland Avenue, Phoenix, AZ, 85016, US

(21) Appl. No.: 10/180,787

(22) Filed: Jun. 25, 2002

(51) Int. Cl. H03G 3/00; H04B 1/00

(52) U.S. Cl. 381/119; 381/61; 369/63

(57) ABSTRACT

A method of creating and duplicating recordings of a live performance for virtually immediate distribution to attendees of such live performance includes the pre-sale of such recordings before or during such performance. During the performance, audio analog signals are converted into digital audio signals and stored by a personal computer as a continuous digital recording. During the performance, the digital recording of such performance is sub-divided into tracks and a master disc is created of the sub-divided recording. One or more of such master discs are then inserted into one or more mass disc duplicators for rapidly producing copies thereof. The copies are then distributed to the attendees of the live performance who have purchased such copies in advance.

### BACKGROUND OF THE INVENTION

1. Field of the Invention

The present invention relates generally to recordings of live performances, and more particularly, to a method and apparatus for producing such recordings in volume relatively soon after such performance is completed.

2. Description of the Relevant Art

Live entertainment concerts have been very popular for many years and frequently draw large audiences. For example, it is believed that over 28 million people attended the fifty largest domestic tours in the year 2000. Many performers, most notably rock-and-roll bands, will release a new album of songs and then promote the album by going on a tour of different cities to perform new songs during live concerts. Performers often interject comments between songs during the live concert, and the audience often reacts to such comments. Thus, live concerts often provide a form of entertainment that extends beyond the soundtracks recorded on a studio album; indeed, some performers release albums that were recorded “live” at a concert hall or other venue to capture the exchanges between the performers and the audience, along with the applause, cheering, and reaction of the fans. Apart perhaps from purchasing a hat or tee-shirt at the concert, there is no satisfactory way for concert goers to preserve and experience such concerts again.

Concert halls and other venues at which such live concerts are performed typically include a sound mixing board for adjusting volume levels of on-stage microphones in order to balance the vocal and instrumental sounds that are amplified and driven onto loudspeakers located within the concert hall or other venue. Such soundboards are usually operated by either an engineer employed by the performers or employed by the concert venue. Some performers have, in the past, permitted fans in the audience to “patch into” the sound mixing board to record “live” versions of a concert. In other cases, concert goers have been known to simply smuggle in small recording devices to illegally record so-called “bootleg” versions of a live concert, which deprive performers and recording companies from revenue that they might otherwise have collected. In either case, the quality of such recordings is compromised, and the recording typically is made on magnetic tape without any clear divisions between the end of one song and the start of a next song. Such magnetic taped recordings do not have the quality or permanence of compact disc (CD) recordings. Moreover, recordings made using the conventional concert hall soundboard do not readily capture the crowd noises that are an essential part of a live concert or other live performance.

Accordingly, it is an object of the present invention to provide a method of producing and distributing recordings of live musical performances to fans attending such concerts shortly after such performances are completed.

Another object of the present invention is to provide such a method wherein such recordings can be made in the form of conventional compact discs (CDs).

Still another object of the present invention is to provide such a method wherein the recording is divided into conventional song tracks for allowing a playback device to detect and index the various tracks recorded on such recording.

Yet another object of the present invention is to provide an efficient, quick, unobtrusive method of producing high quality, live performance recordings of a performance while requiring relatively little, if any, assistance from the performing artists.

A further object of the present invention is to create an additional revenue stream for live performers while allowing those attending a concert or other performance to be able to “re-live” the concert at a later time.

These and other objects of the present invention will become more apparent to those skilled in the art as the description of the present invention proceeds.

### SUMMARY OF THE INVENTION

Briefly described, and in accordance with a preferred embodiment thereof, the present invention relates to a method of recording, mass-producing, selling and delivering authorized, high-quality, digital reproductions of live performances to audience members, a relatively short time after completion of such live performance. In practicing such invention according to one aspect thereof, a sound mixer is provided for receiving at least one, and typically two or more, audio sources; each audio source can originate with the live performer(s) or from the audience attending such performance. The sound mixer is coupled to a personal computer for creating and storing a digital representation of the sounds being recorded, i.e., a master digital image. Preferably, this step of coupling the sound mixer to the personal computer includes the conversion of audio analog signals provided by the sound mixer into digital audio signals for use by the personal computer.

In one preferred embodiment of the present invention, the personal computer is either equipped with, or a coupled to, a master disc burner; using the disc burner of the personal computer, at least one master disc is created containing the master digital image of the audio sources recorded during the live performance. A disc duplicator, capable of generating a number of distribution discs based upon the master digital image, is then used to create distribution discs for distribution to persons desiring such recordings. The master digital image can be transferred from the personal computer to the disc duplicator either by creating a master compact disc and physically transferring the master compact disc to the disc duplicator, or by electronically downloading the master digital image directly from the personal computer to the disc duplicator.

Assuming that the live performance takes place inside a structure, the sound mixer and personal computer, which are relatively compact, are preferably located inside such structure; the disc duplicator may be located outside the performing structure, such as in a mobile van. To enhance the quality of the recording of the performer, at least one of the audio sources received by the sound mixer is preferably a concert hall soundboard for providing the sounds made by performers; alternatively, the sound mixer might receive the input signals that are being fed to the concert hall soundboard. To allow those who attended the performance to better re-experience such performance, at least one of the audio sources received by the sound mixer is preferably a microphone for recording sounds made by the audience during the performance.

In accordance with another aspect of the present invention, an apparatus for creating and duplicating recordings of a live performance includes a sound mixer located inside the performing venue for receiving at least one, and typically two or more audio sources that originate with the performer and/or the attending audience. Preferably, at least one of such audio sources consists of sounds made by a live performer, and at least one other audio source is a microphone sensitive to sounds made by the attending audience. A personal computer, preferably a mobile laptop computer, is coupled to, and is preferably located near, the sound mixer for receiving the mixed audio signals, and stores digital representations of such audio signals as a master digital image. Preferably, the aforementioned duplicating apparatus also includes an analog audio capture interface coupled between the sound mixer and the personal computer for converting the sound mixer's analog audio signals into digital audio signals for use by the personal computer. In one preferred embodiment, the personal computer is equipped with, or coupled to, a master disc burner for transferring stored digital sounds of the master digital image onto a master compact disc. A multiple disc burner, which may be located outside the performing venue, e.g, in a mobile van parked outside, is adapted to receive the master digital image created by the personal computer, either via a master compact disc, or by downloading the stored master digital image directly into the multiple disc burner. The multiple disc burner is also adapted to receive a number of blank compact discs. The multiple disc burner simultaneously copies the digital audio signals already recorded within the master digital image onto the blank compact discs.

### BRIEF DESCRIPTION OF THE DRAWINGS

FIG. 1 is a block diagram illustrating the basic components used to make a master compact disc recording inside the performing venue in accordance with the preferred embodiment of the present invention.

FIG. 2 is a sectional drawing of a mobile van housing multiple disc burners for generating production discs to be distributed to persons who have attended a live performance.

FIG. 3 is a computer screen shot of the screen of a personal computer being used to make a master compact disc, with the applicable software running, but without recording any sounds.

FIG. 4 is a second computer screen shot of the screen of a personal computer being used to make a master compact disc, with the applicable software running, and in the process of digitally recording sounds.

FIG. 5 is a third computer screen shot of the screen of a personal computer being used to make a master compact disc, with the applicable software running, and in the process of digitally recording sounds, but with the File/Quit option displayed on the screen.

### DETAILED DESCRIPTION OF THE PREFERRED EMBODIMENTS

As set forth above, it is an objective to create, reproduce and distribute recordings of a live performance to persons who attended such performance, shortly after such live performance has ended. Applicants have found that most concert goers are willing to wait up to about 30 minutes after the final encore of a live entertainment show for a custom CD capturing the live performance that such persons just attended. Sales of such CDs can begin when the venue opens, using multiple points of purchase where possible. A voucher is distributed for each CD purchased. These vouchers are then surrendered once the concert or other performance is over, at one or more designated locations for distributing the finished CD, thereby separating the sales phase from the CD production/delivery phase. CD sales can occur before, during and after the event. Once the event is over, attendees can be given the option to wait in line to pick up the CDs as they are produced or fill out the back of the voucher with a delivery address where the CD will be shipped the following day. If the option is given, it may reduce the wait time and allow a larger volume of CDs to be sold than would normally fit into the 30-minute time frame. Ideally, the duplicated CDs are distributed shortly after the concert or other performance has ended, and concert goers are leaving the concert hall or other venue to walk to their vehicles to go home for the evening, perhaps at one or more concession stands in the parking lot of the performance venue. As mentioned earlier, for those who can not stay for a few minutes after the concert or other performance, their ordered CD can be mailed to them on the following day.

In order to properly capture ambient noise from the crowd and the surroundings, at least two microphones are positioned inside the structure in which the live performance is being conducted. Referring to FIG. 1, microphones 10 and 12 are used to capture sounds made by the audience attending the live performance. In larger venues, perhaps four or five such microphones are placed in order to sample the entire audience. These microphones are brought into the performing venue by the firm responsible for duplicating the compact disc recordings of the live performance, and are preferably condenser microphones of the type commercially available from AKG Acoustics of Nashville, Tenn. under Model No. AKG-414. Similar microphones 14 and 16 are typically used on-stage by the performers who are singing and/or playing musical instruments.

Audience microphones 10 and 12 are coupled directly to input ports of a compact sound mixer 18 that is brought into the performing venue by the firm responsible for duplicating the compact disc recordings of the live performance. Preferably, sound mixer 18 is of the type commercially available from Mackie Designs of Woodinville, Wash. under Model No. 1202-VLZ Pro. Sound mixer 18 produces stereo output signals 20 and 22 in analog form. Other input ports of compact sound mixer 18 are coupled to the soundboard 24 that is usually present in the performing venue; this soundboard is usually controlled by a sound engineer employed by the performers, or in other cases, employed by the concert hall, theater, or other venue where the performance is being held. Soundboard 24 is coupled to the on-stage microphones 14 and 16, musical instrument amplifiers 26, and any other sound sources controlled by the performers. Alternatively, sound mixer 18 could directly sample the same input signals that are directed to soundboard 24, i.e., the signals produced by microphones 14 and 16 and amplifier 26. In either case, compact sound mixer 18 samples both audio signals of the live performance, as well as the audience reaction thereto. It is often convenient to set up compact sound mixer 18 close to the concert hall soundboard 24.

Preferably, the analog stereo output signals 20 and 22 from sound mixer 18 are coupled to a laptop personal computer 28 using one or more audio processing coupling devices to enhance the incoming audio signals. For example, in the preferred embodiment, stereo analog signals 20 and 22 are coupled to input terminals of a balancing device 30 commercially available from TC Electronic Inc. of Westlake Village, Calif. under the trademark “Finalizer Express”. Balancer 30 normalizes sound levels on stereo analog signals 20 and 22 automatically, thereby improving the quality of the sound signals passed therethrough. The output 32 of balancer 30, which may actually be a two-channel stereo signal, is then passed into an accessory device 34 known as a cable-type USB analog audio capture interface commercially available from Edirol Corporation North America of Bellingham, Wash. under Model No. UA-1A; audio capture device 34 includes an output terminal 36 which plugs into the USB port of laptop computer 28. Audio capture device 34 converts the analog audio signals from sound mixer 18, as modified by balancer 30, into digital format for processing and storage by personal computer 28. While it has been found that the aforementioned balancer 30 and audio capture device 34 improve the quality of the sound recorded by personal computer 28, it is possible to omit such devices, and to instead couple stereo output signals 20 and 22 of sound mixer 18 directly into the “Line In” port of personal computer 28, if desired. Personal computer 28 includes a hard drive for storing digital audio signals that can reproduce the audio signals output by sound mixer 18. Preferably, a buffer area of random access memory (RAM) within personal computer 28 is used to temporarily store incoming digital audio signals before they are written to the hard drive; this allows the hard drive to perform maintenance operations without the risk of losing digital audio signal data. This 30-second buffer also allows the recording technician to divide the recording into tracks, in a manner to be described in greater detail below. The digital audio signals are typically stored on the personal computer hard drive as uncompressed audio “wave” (.wav) files.

Personal computer 28 preferably includes a CDROM burner which, for clarification of FIG. 1, is shown as separate block 38, though CDROM burner 38 is preferably integral with personal computer 28, though it could be an external CDROM coupled to personal computer 28 via a USB port, for example. Based upon digital audio signals stored on the hard drive of personal computer 28 (i.e., the “master digital image”), music, voices or other sounds captured during the live performance are written to, or “burned into”, a blank CDROM disc, thereby producing master disc 40.

The software which runs on the personal computer allows the recording technician to insert tracks into what would otherwise be one long, continuous recording session. The user decides, as part of an editing process, when the applause and any related performer comments have been completed regarding one song or performance, and terminates the track at that point. A new track then starts just after the preceding track ended. These tracks need not be periods of silence. Indeed, the produced CDs can be so-called “disc-at-once” (DAO) CDs wherein the end of one track, and the start of the next track are indistinguishable to the listener, and yet CD players can sense such tracks and skip from one track to the next.

Most CDs are capable of recording approximately 74 minutes worth of sound. Thus, for a concert or other performance of 74 minutes or less, one CD is all that is required to capture the entire concert. If the concert extends slightly beyond 74 minutes, some portions of the performance can be edited out to stay within the 74 minute boundary. On the other hand, some performers routinely perform for 90 minutes or more; in this case, a dual-set CD can be distributed, wherein the first CD is mastered and duplicated during the usual intermission, while the second CD is mastered and duplicated immediately after completion of the concert or other performance.

Once a master disc has been produced, typically just minutes after the performance has ended, the master disc is inserted into one or more large scale CD-R duplicators to make the distribution copies of the recording. Note that in a case where a performance runs more than 74 minutes, the master disc containing the first 74 minutes of the performance can be input to a CD-R duplicator while the second half of the performance is proceeding. Thus, the second half of the performance can be recorded at the same time that CDs containing the first half of the performance are being mass-duplicated, even in the absence of an intermission.

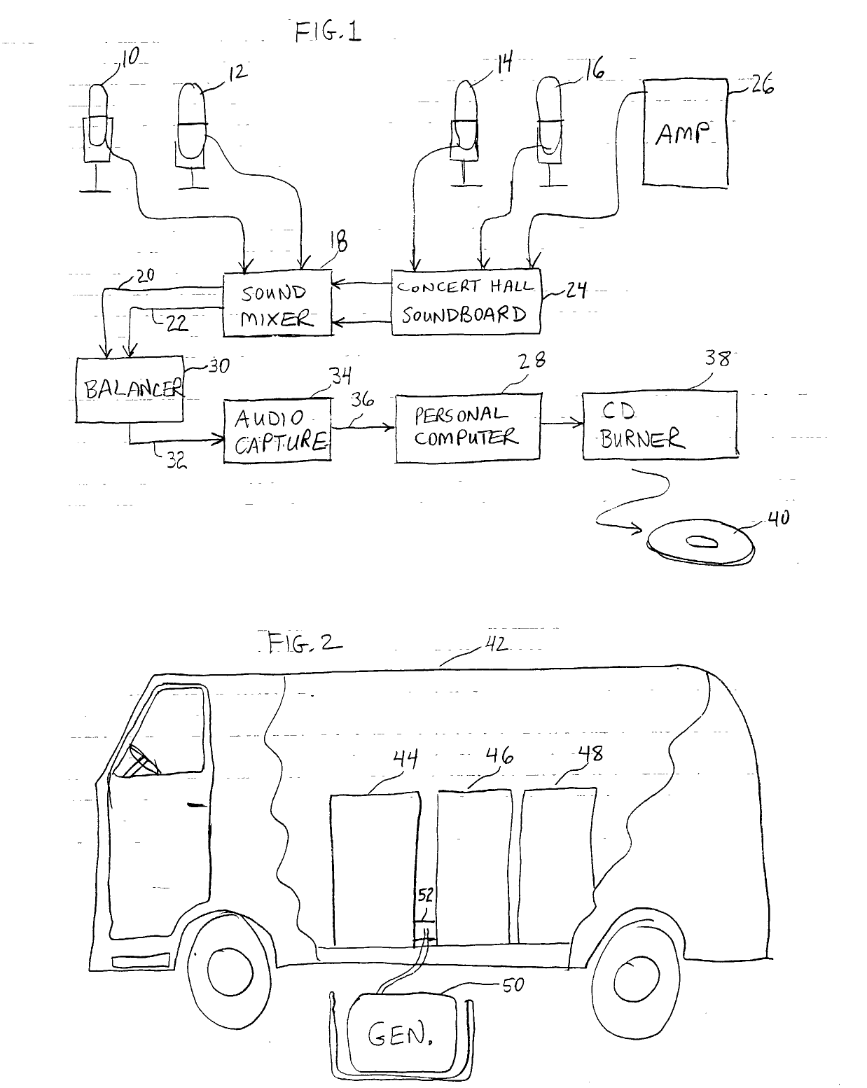

The mass duplicating equipment is preferably installed in custom, self-contained trailers and/or vans known as “Mobile Bum Units” (MBUs) for use on location. One such MBU is illustrated in FIG. 2 and is generally designated by reference numeral 42. The MBUs are modular, self-contained, climate-controlled units (trucks, vans or trailers) with clean power generators, audio recording equipment, computers, CD duplication and labeling gear, storage areas and workspace for technicians. Small MBUs can be used for local events and can produce 180 CDs within the 30 minute time period following the end of a concert or other performance. Each regular-size MBU is capable of producing about 640 CDs in the allotted 30-minute time period. For concerts or other performances where more CDs are needed, multiple MBUs can be deployed. One such MBU might follow a performing band from city to city while on tour from one venue to the next. The MBUs and their contents are designed to withstand the rigors of road travel. They quickly can be changed from “travel-ready” mode to “operational” mode and vice versa. In travel mode, everything is secured and space is used efficiently. In operational mode, the units provide a cool, comfortable environment for the equipment and the technicians operating it. Each MBU preferably maintains a controlled climate so that the duplicating equipment and personnel are not subject to unnecessary variations in weather conditions. Each MBU also preferably includes workspace for assembling the CD packages, i.e., inserting duplicated discs into labeled jewel cases.

Referring again to FIG. 2, MBU 42 is equipped with large commercial CD burners 44, 46, and 48 available from Otari Corporation of Canoga Park, Calif., a subsidiary of Otari Japan. Each such CD burner is preferably of the type sold by Otari as the “Otari CDP-64 Large-Scale CD-R Duplication Unit”, having 64 CD-R drives. Each of these mass duplicators are capable of generating up to 500 finished CD discs (each of 70-minute program length) per hour, or 250 such CDs per 30-minute period. Such Otari CD duplicators use high-speed 12×CD-R drives that can complete duplication of 74-minute discs within about 8 minutes per disc. Thus, one such Otari burner can produce 64 finished discs in eight minutes. As shown in FIG. 2, MBU 42 includes its own gas-powered electrical generator 50, the output voltage of which is regulated by regulator 52 to provide a stable electrical supply for CD duplicators 44, 46 and 48. While the preferred embodiment of the invention mounts the mass disc duplicators in mobile MBUs, it is also possible to install such mass duplicating equipment on a more permanent basis at a concert venue that frequently hosts such performances. Of course, smaller-scale mobile burn units can also be created, using conventional vans or sport utility vehicles equipped with 16 or 32 CD-R burners for small venues at lower cost.

If four of the aforementioned Otari CD-R burners are provided within an MBU, then they can collectively produce approximately 256 finished CDs every 8 minutes. Assuming a goal of delivery within 30 minutes of the end of the concert or other performance, then four such Otari burners could produce from 768-1,024 CDs per 30-minute period. In order that each of the four CD-R duplication units be permitted to start running as soon as possible, it is desirable to produce four master CDs at once (one for each CD-R duplication unit). Normally, a personal computer includes only one CD-R burner. Four master CDs can be created simultaneously by connecting three more CD burners to the aforementioned personal computer using a so-called “firewire” connection scheme between the personal computer and the other three burners.

Prior to each concert's sound-check, a technician sets up the recording equipment, oversees the placement of the ambient, stereo microphones and cables, and patches the sound mixer into the soundboard of the concert hall or other venue. During the usual sound-check, recording levels are checked and set. During the actual show, a technician monitors the recording and makes adjustments or compensations as necessary. The sound engineer makes sure that the mix of audience and ambient sound, and the sound from the performer's soundboard, is optimal.

During the recording of the performance, the recording technician inserts breaks between successive tracks at appropriate points. These break points are established at the discretion of the recording technician somewhere between the end of one song or performance and the beginning of the next song or performance. Ideally, the audience reaction to the conclusion of one song is kept within the track that contains such song, whereas the audience reaction to the announcement of a next song is maintained within the track containing the next song. The recording software programmed on the laptop personal computer, used by the audio engineer to record the performance, allows the audio engineer to easily monitor the recording process, to set and label tracks, and to quickly burn the master CD that is needed by the high-speed burn units. The master CD is then transported to the CD duplicating equipment and used to burn distribution copies. The Burn Technician begins the duplicating process, creating as many CDs as are needed to fulfill the demand.

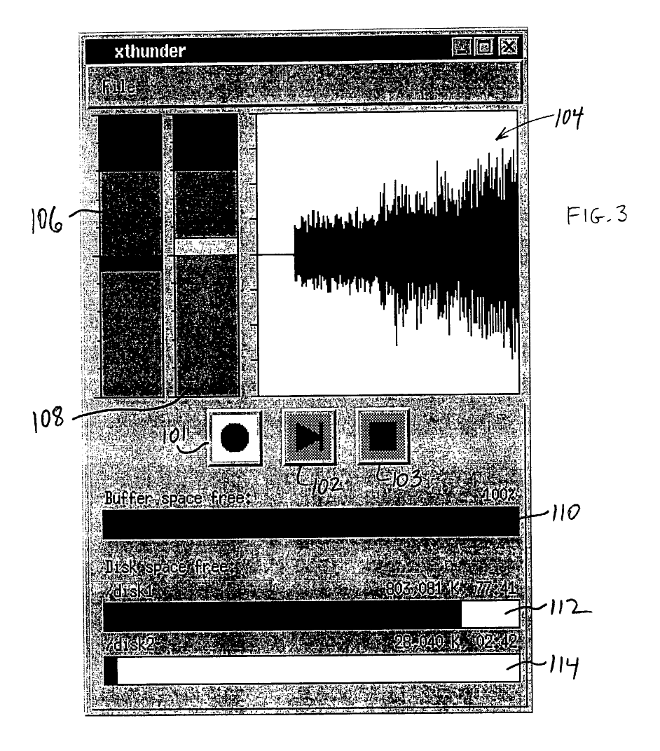

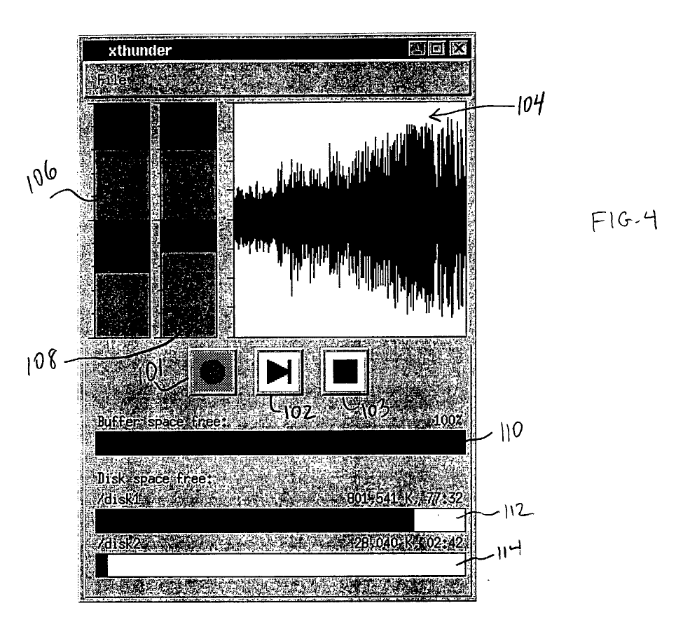

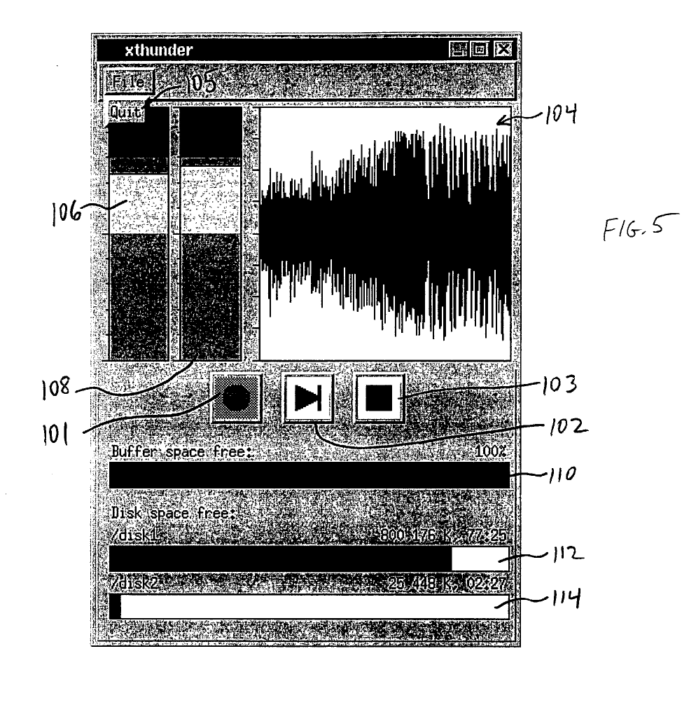

The recording software used to process, store, and burn digital audio signals onto the master disc will now be described in greater detail. Before describing the flow of the main software program, it is helpful to first become familiar with the computer screen display that is seen by the recording engineer when such software is running, as indicated in accompanying FIGS. 3, 4 and 5. These figures illustrate the appearance displayed on a user's computer screen when using the main program of the present invention to record the master digital image. “Record” button 101 is used to start recording; a user positions a mouse cursor over such button and “clicks” the mouse to toggle “record” button 101. In FIG. 3, the software program is running, but no recording is taking place. Record button 101 is “enabled” in FIG. 3 in the sense that the Record button can be “depressed” to start recording. In FIGS. 4 and 5, the software program is running, and digital sounds are being recorded onto the computer's hard drive; thus, in FIGS. 4 and 5, Record button 101 is “disabled” in the sense that it may not be toggled during recording. To stop recording, either the Stop button 103 or the Quit menu item 105 is “depressed”, in the manner explained below.

“Next” button 102 is used during recording to end one track of the master digital image, and to start the next succeeding track. In FIG. 3, Next button 102 is disabled, since FIG. 3 corresponds to a period when no recording is taking place. Next button 102 is enabled in FIGS. 4 and 5, when recording is taking place.

“Stop” button 103 is used to terminate recording of the master digital image until Record button 101 is pressed once more. Stop button 103 is disabled in FIG. 3, as there is no need to stop recording when recording is not taking place. Stop button 103 is enabled in FIGS. 4 and 5 when recording is taking place.

Referring to FIGS. 3-5, rectangular display area 104 in the upper right portion of the computer screen display is a scrolling graphical display that shows the combined amplitude, or intensity, of the audio signals for both the left and right stereo channels that are available for recording. The most recent sound signal strength is displayed at the very right side of display area 104, and that information scrolls toward the left side of display are 104 as new audio data becomes available.

Referring to FIGS. 3-5, a pair of graphical “meters” 106 and 108 in the upper left portion of the computer screen display are used to separately indicate audio signal strength for each of the left and right stereo channels that are available for recording. Colored bands of red, yellow and green are presented in each such “meter” to indicate the graphical level of audio input which represents left and right channels.

In the lower half of the computer screen display shown in FIGS. 3-5, horizontal meter bar 110 displays the free amount of buffer space available at any given time. A portion of the computer's random access memory is set aside to act as a buffer to store approximately thirty seconds worth of digital audio signals before they are available for recording onto the computer's hard drive. This allows the recording engineer a thirty second preview of such sounds before they are actually recorded. The buffer space free meter indicates the amount of free buffer space available for temporarily storing additional digital audio signals. The lower portion of the computer screen display also includes a pair of disk space free meter bars 112 and 114 to indicate the amount of free space remaining on each of first and second hard drives used to permanently record digital audio signals. These indications are expressed both graphically, as well as by displaying the amount of available disk space in both kilobytes and minutes/seconds of recording time.

With the foregoing explanation of the computer screen display in mind, the main program flow will now be described in greater detail. The flow of the main software program can be understood in conjunction with the following steps:

1. read configuration file (audio parameters, directory list)

2. set up and display user interface (enable record button, disable next and stop buttons)

3. start audio input thread

4. start monitor thread

5. start disk monitor thread

6. wait for user input

7. has the “record” button been pressed?

a. if not, then go to step 8;

b. If so,then:

(i) disable the “record” button;

(ii) enable the “next” button;

(iii) enable the stop button;

(iv) advise audio input thread that “record” is true;

(v) start wavefile thread;

(vi) return to step 6.

8. has the “next” button been pressed?

a. if not, then go to step 9;

b. if so, then:

(i) advise wavefile thread that “next” was pressed;

(ii) return to step 6.

9. has the “stop” button been pressed?

a. if not, then go to step 10;

b. if so, then:

(i) enable the “record” button;

(ii) disable the “next” button;

(iii) disable the stop button;

(iv) advise wavefile thread that “stop” was pressed;

(v) advise audio input thread that “record” is false;

(vi) return to step 6.

10. did user click on “quit” from “File” pulldown menu?

a. if not, then go back to step 6;

b. if so, then:

(i) advise wavefile thread to “stop”;

(ii) advise disk monitor thread to “stop”;

(iii) advise monitor thread to “stop”;

(iv) advise audio input thread to “stop”;

(v) exit program.

In step 1 above, the software program is configured, for example, by establishing the hard drive directory into which the new digital audio file is being created, etc. For example, the software program retrieves a file from the user's home directory, which file might resemble the following:

Directory/dosd

Directory/home/user

Device/dev/dsp1

Channels 2

Bits 16

Rate 44100

In the file above, the two “Directory” lines are used to monitor available disk space, and to specify the directory into which .wav files are to be created once recording begins. The “Device” line specifies which audio device is the source of the sounds to be recorded; in this example, device “dsp1” specifies the USB port audio driver. The “Channels 2” line tells the software that two input channels are being provided for recording stereo sound. The “Bits 16” line tells the software that the input signals are being provided as 16-bit signed samples (or two data bytes). The “Rate 44100” line tells the software that it will record audio signal samples at the rate of 44,100 samples per second. Thus, in this example, for each second of recording, 2 (two channels)×2 (two bytes per 16-bit sample)×44,100 (samples per second), or 176,400 bytes of data must be written to memory.

Step 2 causes the user interface screen (see FIG. 3) to be displayed on the user's computer screen, and enables Record button 101, and disables Next button 102 and Stop button 103. Step 3 starts the audio input thread routine, described in greater detail below, for accessing incoming digital audio signals. Step 4 starts the monitor thread routine, described in greater detail below, for controlling the display of scrolling graph 104, meters 106 and 108, and buffer space free meter 110. Step 5 starts the disk monitor thread routine, described in greater detail below, for displaying available disk space on meter bars 112 and 114. At this stage, the user's computer screen appears similar to the form shown in FIG. 3.

Having configured the user's computer screen display, the main program now waits for user input, represented by step 6, e.g. by detecting that the user has clicked a mouse button. If user input is detected, then the main program needs to determine the nature of the input. In step 7, the main program checks to see whether the user “depressed” Record button 101; if not, flow proceeds to step 8. If Record button 101 has been depressed, then the main program disables Record button 101, enables Next button 102, and enables Stop button 103. Step 7 also alerts the aforementioned audio input thread routine that “record” is now true, i.e., that recording of digital audio signals onto the hard drive is now desired. Likewise, step 7 also activates a wavefile thread routine, described in greater detail below, to start building a new “.wav” file on the computer's hard drive. The recording phase, represented by FIG. 4, has now been established. Control in the main program is then passed from step 7 back to step 6 to wait for additional user input.

In step 8, since Record button 101 has not been depressed by the user, the main program checks to see whether it was Next button 102 that had been pressed by the user. If not, then flow proceeds to step 9. However, if Next button 102 was depressed, then the main program knows that the user has requested that the user has requested insertion of a track break at this point in the recording. In that case, step 8 advises the aforementioned wavefile thread routine that Next button 102 was pressed to start the new track. Control in the main program is then passed from step 8 back to step 6 to wait for further user input.

In step 9, the main program checks to see whether Stop button 103 has been depressed by the user. If not, then control is passed to step 10. However, if Stop button 103 has been pressed, then recording must be stopped, and the user's screen must be returned to its appearance in FIG. 3. Accordingly, in step 9, the main program re-enables Record button 101, disables Next button 102, and disables Stop button 103. Step 9 also alerts the wavefile thread routine that Stop button 103 was pressed to avoid further processing of incoming audio signals, and also advises the aforementioned audio input thread routine that “record” is now false, i.e., that further recording of digital audio signals onto the computer's hard drive should halt. Control is then passed back to step 6 to await further user input.

Finally, in step 10, the main program checks to see whether the user clicked on Quit button 105 (shown in FIG. 5) from “File” pull-down menu. If not, then control is passed back to step 6 to await further user input. If the user did click on Quit button 105, then the user desires to exit the software program. In this case, step 10 advises each of the wavefile thread, disk monitor thread, monitor thread, and audio input thread, routines to “stop”, and the software program then terminates.

The aforementioned audio input thread routine operates in the following manner. When the audio input thread is “started”, it triggers the audio input device, such as audio capture block 34 or the computer's internal soundcard, to begin processing incoming audio signals into “.wav” file data. The audio input thread routine also sets up a circular queue in the computer's random access buffer memory able to hold 30 seconds of 0.2-second long blocks of digital audio data. Thus, the buffer memory holds up to 150 of such 0.2-second long blocks of digital audio data at any point in time. Initially, a “recording” flag is set to “false” to indicate that the user has not yet requested recording of digital audio signals.

The audio input thread then checks to see whether the main program has sent a “stop” message. If so, then the audio input device is closed, and the audio input thread routine is terminated. If no “stop” message was received, then the audio input thread routine checks to see whether the main program has transmitted a “record” message or a “norecord” message. If the main program sent a “record” message, then the “recording” flag is changed to “true”. Alternatively, if the main program has transmitted a “norecord” message, then the “recording” flag is changed to “false”.

The audio input thread then reads the next 0.2-second block of audio data from audio input device, and adds this new block to the circular queue. If the “recording” flag is false, then the circular queue is flushed of all data except for the most recently sampled 0.2-second block of audio data. If the “recording” flag is true, then the audio input thread routine checks to see if the circular queue is now full, i.e., does it now contain 150 0.2-second blocks of audio data; if so, then the audio input thread routine causes the user's computer screen to display an “overrun” warning error message indicating that some audio data has been lost. This should not happen, however, because the wavefile thread routine catches and removes the oldest 0.2 second block of data from the circular queue before it falls off the circular queue.

The wavefile thread routine, upon being started, opens a new “.wav” file in the selected directory of the selected hard drive. A file-naming algorithm is used wherein the file name “001.wav” is attempted. If that file name already appears in the selected directory, then the file name “002.wav” is attempted, and so forth, until an unused file name is established. The wavefile thread then checks to see if a “stop” message has been received from the main program (indicating that the user has pressed Stop button 103 or Quit button 105); if so, then the current “.wav” file is closed, and the wavefile thread routine is terminated.

Assuming that no “stop” message has been received, the wavefile thread routine waits for the newest 0.2-second block of audio data to be completed, and then strips from the end of the aforementioned circular queue the oldest 0.2-second block of audio data so that it can be appended onto the current “.wav” file being constructed on the computer's hard drive.

After stripping off the oldest 0.2-second block of audio data and adding it to the current “.wav” file, the wavefile thread routine then checks to see whether a “next” message has been received from the main program (indicating that the user has pressed Next button 102). If not, control is passed back to the aforementioned “stop” message test for testing for receipt of a “stop” message, as described above. On the other hand, if a “next” message has been received, then the current “.wav” file is closed (completing the current “track”), and the next “.wav” file is opened (initiating a new “track”). Each such written “.wav” file will be a multiple of 2,352 bytes of data, since there are 2,352 bytes of audio data in the “.wav” file for each 0.2-second block of recorded sound. Control then passes back to the “stop” message test described above.

The monitor thread routine, after being started, first checks to see whether a “stop” message has been received from the main program; if so, the monitor thread routine terminates. If not, then the monitor thread routine waits for the newest 0.2-second block of audio data to be added to the circular queue. Once the newest 0.2-second block of audio data is added to the queue, the monitor thread routine analyzes the digital audio signals within such audio block to compute the maximum amplitude and minimum amplitude for each of the left and right stereo channels within such 0.2-second block of audio data. Based upon such computations, the red, yellow, and green meter bands displayed in meter bars 106 and 108, and the amplitude of the combined left and right channels displayed in scrolling graph 104, are modified to reflect current levels for the most recently-sampled 0.2-second block of audio data. Once again, the new data for the most recent 0.2-second block of audio data is displayed at the right edge of scrolling graph 104, and the corresponding data for previous 0.2-second blocks of audio data scroll to the left. The display meter 110 for free buffer space is updated at this point; while FIGS. 3-5 show free buffer space both graphically and as a percentage of the total, the computer screen display can also display data showing the number of kilobytes of memory, and the corresponding number of seconds of audio data, that can be held in the buffer before data loss will occur. Control is then sent back to the top of the routine to again check to see if a “stop” message has been received.

Finally, the disk monitor thread routine, upon being initiated by the main program, first checks to see if a “stop” message has been received from the main program; if so, then the disk monitor thread routine terminates. If not, then the disk monitor thread routine re-calculates the free space available in each of the two selected hard drive directories, and the graphical displays in meter bars 112 and 114 are updated. After updating these meter bars, the disk monitor thread routine waits for one second to pass, and control is then returned to the top of the routine to again check for receipt of a “stop” message from the main program.

Currently, the most common format of digital music on compact discs is so-called Phillips CD DA technology. However, if desired, the CDs that are mass duplicated using the aforementioned method can use other digital signal formats, including MP3, VCD, DVD, or some hybrid of these. DVD formatted discs could even include brief amounts of video footage in addition to the audio signals recorded during the concert, performance, conference, etc.

Since the disc recordings of such live performances are produced in limited quantities, and are normally available only at the event itself, these compact disc recordings are a unique souvenir, and collector's item, of any live performance. By recording and producing such live performance CDs, performers and producers create another revenue stream from every live performance with almost no additional effort on their part. By utilizing specialized digital recording and fast CD mass reproduction techniques in unique mobile production facilities, the present invention is able to offer concert-goers an opportunity to instantly re-live and enjoy live music performances. The present invention provides almost real-time capture of audio performances, and rapid reproduction of the finished CD once a show is over.

While the present invention has been described primarily as being used for recording and distributing compact discs of live musical group performances, the present invention can also be used to distribute recordings of business/corporate and social events, lecturers, motivational speakers, and functions by churches and/or charitable organizations. For example, some corporations make big productions out of annual meetings, new product announcements and client workshops, seminars, trade shows etc. Some even hire well-known musical bands to perform at these events. These performances, along with CEO speeches and related company announcements can be distributed to attendees as a nice “take home” piece to help maintain the momentum of the event. The cost of producing and distributing such CDs in the case of a corporate event would likely be a small portion of the relatively large sums often spent on such events.

While the present invention has been described with respect to preferred embodiments thereof, such description is for illustrative purposes only, and is not to be construed as limiting the scope of the invention. Various modifications and changes may be made to the described embodiments by those skilled in the art without departing from the true spirit and scope of the invention as defined by the appended claims.

We claim:

1. A method of creating and duplicating recordings of a live performance comprising the steps of:
a. providing a sound mixer for receiving at least one audio source;
b. coupling the sound mixer to a personal computer to provide audio signals thereto;
c. coupling the personal computer to a disc burner;
d. using the disc burner to create a master disc containing at least one audio source recorded during the live performance;
e. providing a disc duplicator capable of generating a plurality of distribution discs based upon a master disc; and
f. using the disc duplicator to create a plurality of distribution discs based upon the master disc for distribution to persons desiring such distribution discs.

2. The method recited by claim 1 wherein the sound mixer and personal computer are located inside a structure in which the live performance is taking place, and wherein the disc duplicator is located outside the structure in which the live performance is taking place.

3. The method recited by claim 2 wherein the method comprises the further step of providing the disc duplicator in a vehicle that can be temporarily located near the structure in which the live performance is taking place.

4. The method recited by claim 1 wherein the at least one audio source received by the sound mixer is a microphone for recording sounds made by an audience attending such live performance.

5. The method recited by claim 1 wherein the at least one audio source received by the sound mixer is a source of sounds being made by a live performer.

6. The method recited by claim 1 wherein the at least one audio source received by the sound mixer is a concert hall soundboard for providing sounds made by a live performer.

7. The method recited by claim 6 wherein the sound mixer also receives sounds from a microphone sensitive to noises made by the audience attending the live performance.

8. The method recited by claim 1 wherein the step of coupling the sound mixer to the personal computer includes the step of converting audio analog signals provided by the sound mixer into digital audio signals for use by the personal computer.

9. The method recited by claim 1 wherein the disc burner is provided integral with the personal computer.

10. A method of creating and duplicating recordings of a live performance comprising the steps of:
a. providing a sound mixer for receiving at least one audio source;
b. coupling the sound mixer to a personal computer to provide audio signals thereto;
c. using the personal computer to create and store a master digital image of sounds made during such live performance;
d. providing a disc duplicator capable of generating a plurality of distribution discs based upon the master digital image;
e. transferring a copy of the master digital image from the personal computer to the disc duplicator; and
f. using the disc duplicator to create a plurality of distribution discs based upon the master digital image.

11. The method recited by claim 10 wherein the sound mixer and personal computer are located inside a structure in which the live performance is taking place, and wherein the disc duplicator is located outside the structure in which the live performance is taking place.

12. The method recited by claim 11 wherein the method comprises the further step of providing the disc duplicator in a vehicle that can be temporarily located near the structure in which the live performance is taking place.

13. The method recited by claim 10 wherein the at least one audio source received by the sound mixer is a microphone for recording sounds made by an audience attending such live performance.

14. The method recited by claim 10 wherein the at least one audio source received by the sound mixer is a source of sounds being made by a live performer.

15. The method recited by claim 10 wherein the at least one audio source received by the sound mixer is a concert hall soundboard for providing sounds made by performers.

16. The method recited by claim 15 wherein the sound mixer also receives sounds from a microphone sensitive to noises made by the audience attending the live performance.

17. The method recited by claim 10 wherein the step of coupling the sound mixer to the personal computer includes the step of converting audio analog signals provided by the sound mixer into digital audio signals for use by the personal computer.

18. The method recited by claim 10 wherein the plurality of distribution disks are created and distributed within 24 hours of the completion of the live performance.

19. The method recited by claim 10 wherein the plurality of distribution disks are created and distributed within 12 hours of the completion of the live performance.

20. The method recited by claim 10 wherein the plurality of distribution disks are created and distributed within 2 hours of the completion of the live performance.

21. The method recited by claim 10 wherein the plurality of distribution disks are created and distributed within 1 hour of the completion of the live performance.

22. The method recited by claim 10 wherein the plurality of distribution disks are created and distributed within 30 minutes of the completion of the live performance.

23. Apparatus for creating and duplicating recordings of a live, the live performance being performed in a performing venue, the apparatus comprising in combination:
a. a sound mixer disposed inside the performing venue for receiving at least one audio source of sounds being made within the performing venue;
b. a personal computer coupled to the sound mixer for receiving the at least one audio source and storing digital representations of such audio source;
c. a master disc burner coupled to the personal computer for recording the digital representations of such audio source onto a master compact disc;
d. a multiple disc burner adapted to receive a master disc created by the master disc burner, and adapted to receive a plurality of blank compact discs, the multiple disc burner serving to duplicate the digital audio signals already recorded on the master compact disc onto the blank compact discs.

24. The apparatus recited by claim 23 including an analog audio capture interface coupled between the sound mixer and the personal computer for converting the analog audio signals output from the sound mixer into digital audio signals provided to the personal computer.

25. The apparatus recited by claim 23 wherein the personal computer is a laptop computer located inside the performing venue proximate to the sound mixer.

26. The apparatus recited by claim 25 wherein the multiple disc burner is located outside the performing venue.

27. The apparatus recited by claim 26 wherein the multiple disc burner is mounted within a mobile vehicle, and wherein the mobile vehicle is located proximate to the performing venue.

28. The apparatus recited by claim 23 wherein the multiple disc burner is located outside the performing venue.

29. The apparatus recited by claim 28 wherein the multiple disc burner is mounted within a mobile vehicle, and wherein the mobile vehicle is located proximate to the performing venue of the personal computer to create a master disc containing the audio sources recorded during the live performance.

30. The method recited by claim 23 wherein the at least one audio source received by the sound mixer is a source of sounds being made by a live performer.

31. The apparatus recited by claim 23 wherein the sound mixer is coupled to a concert hall soundboard for providing to the sound mixer sounds made by performers.

32. Apparatus for creating and duplicating recordings of a live performance, the live performance being performed in a performing venue, the apparatus comprising in combination:
a. a sound mixer disposed inside the performing venue for receiving at least one audio source of sounds being made within the performing venue;
b. a personal computer coupled to the sound mixer for receiving the at least one audio source, the personal computer creating and storing a master digital image of such audio source;
c. a multiple disc burner adapted to receive master digital image stored by the personal computer, and adapted to receive a plurality of blank compact discs, the multiple disc burner serving to duplicate the digital audio signals of the master digital image onto the blank compact discs.

33. The apparatus recited by claim 32 including an analog audio capture interface coupled between the sound mixer and the personal computer for converting the analog audio signals output from the sound mixer into digital audio signals provided to the personal computer.

34. The apparatus recited by claim 32 wherein the personal computer is a laptop computer located inside the performing venue proximate to the sound mixer.

35. The apparatus recited by claim 34 wherein the multiple disc burner is located outside the performing venue.

36. The apparatus recited by claim 35 wherein the multiple disc burner is mounted within a mobile vehicle, and wherein the mobile vehicle is located proximate to the performing venue.

37. The apparatus recited by claim 32 wherein the multiple disc burner is located outside the performing venue.

38. The apparatus recited by claim 37 wherein the multiple disc burner is mounted within a mobile vehicle, and wherein the mobile vehicle is located proximate to the performing venue.

39. The method recited by claim 32 wherein the at least one audio source received by the sound mixer is a source of sounds being made by a live performer.

40. The apparatus recited by claim 32 wherein the sound mixer is coupled to a concert hall soundboard for providing to the sound mixer sounds made by performers.
